(19) United States
(12) Patent Application Publication
(10) Pub. No.: US 2026/0123458 A1
(43) Pub. Date: Apr. 30, 2026

(54) IC PACKAGE STRUCTURE WITH CONNECTIONS AND METHOD OF MANUFACTURING THE SAME

(71) Applicant: CYNTEC CO., LTD., Hsinchu (TW)

(72) Inventor: Yu-Lin Yang, Hsinchu (TW)

(73) Assignee: CYNTEC CO., LTD., Hsinchu (TW)

(21) Appl. No.: 19/059,311

(22) Filed: Feb. 21, 2025

Related U.S. Application Data
(60) Provisional application No. 63/711,158, filed on Oct. 24, 2024.

(51) Int. Cl. H01L 23/495; H01L 21/56; H01L 23/00; H01L 23/31; H01L 25/16; H01L 25/18; H10D 80/30

(52) U.S. Cl. CPC H10W 70/465; H10D 80/30; H10W 74/016; H10W 74/114; H10W 90/00; H10W 74/10; H10W 90/756

(57) ABSTRACT

An IC package structure with connections is provided in the present disclosure, including a die bonded to a leadframe, a plurality of connections bonded to the leadframe, a molding compound formed on the leadframe, a metal layer formed on the molding compound and electrically connecting with the connections, and an electronic component mounted on the metal layer.

### CROSS REFERENCE TO RELATED APPLICATIONS

This application claims the benefit of U.S. Provisional Application No. 63/711,158, filed on Oct. 24, 2024. The content of the application is incorporated herein by reference in its entirety.

### BACKGROUND OF THE DISCLOSURE

### 1. Field of the Disclosure

The present disclosure generally relates to an IC package structure, and more specifically, to an IC package structure with connections and method of manufacturing the same.

### 2. Description of the Related Art

Electronic packaging (or simply “packaging”) can refer to enclosures and protective features built into an electronic product, such as an integrated circuit (IC) chip. Electronic packaging applies both to end products and to components. Packaging of an electronic system must consider protection from mechanical damage, cooling, radio frequency noise emission, protection from electrostatic discharge, maintenance, operator convenience and cost. A semiconductor package can be a metal, plastic, glass or ceramic casing containing one or more semiconductor electronic components. Individual discrete components are typically etched in a silicon wafer before being cut and assembled in a package. The package provides protection against impact and corrosion and dissipates heat produced in the device.

Flat no-leads packages such as quad-flat no-leads (QFN), dual-flat no-leads (DFN) physically and electrically connect IC chips to substrates such as printed circuit boards (PCBs). Flat no-leads, also known as MLF (micro leadframe) and SON (small-outline no leads), is a surface-mount technology, one of several package technologies that connect ICs to the surfaces of PCBs without through-holes. Flat no-lead is a near chip scale package plastic encapsulated package made with a planar copper leadframe substrate. Perimeter leads on the package bottom can provide electrical connections to the PCB. Flat no-lead packages include an exposed thermal pad to improve heat transfer out of the IC (into the PCB). Heat transfer can be further facilitated by metal vias in the thermal pad.

### SUMMARY OF THE DISCLOSURE

To establish signal connection for both the top side and bottom side of an IC package structure and increase component density of a PCB board, the present disclosure hereby provides a novel IC package structure, characterized by connections formed in the molding compound of the IC package structure to electrically connect the components mounted on the molding compound and the leadframe of the IC package structure.

One aspect of the present disclosure is to provide an IC package structure with connections, including: a leadframe; a die bonded to the leadframe; a plurality of connections bonded to the leadframe; a molding compound positioned on the leadframe, wherein the molding compound encapsulates the die and the connections; a metal layer positioned on the molding compound, wherein an end of each of the connections is electrically connected with the metal layer; and an electronic component mounted on the metal layer.

Another aspect of the present disclosure is to provide a method of manufacturing IC package structure with connections, including: providing a leadframe with multiple die pads; adhering a die on each of the die pads of the leadframe; electrically bonding the die to the leadframe; forming a plurality of connections electrically bonded to the leadframe; after the connections are formed, forming a molding compound on the leadframe, wherein the molding compound encapsulates the die and the connections; forming a metal layer on the molding compound, wherein an end of each of the connections is electrically connected with the metal layer; and mounting an electronic component on the metal layer.

These and other objectives of the present disclosure will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-sectional view of an IC package structure with connections in accordance with one embodiment of the present disclosure;

FIG. 2 is a schematic top view of metal layers in several IC package structures with connections in accordance with one embodiment of the present disclosure;

FIG. 3 is a schematic cross-sectional view of an IC package structure with connections in accordance with another embodiment of the present disclosure;

FIG. 4 is a schematic cross-sectional view of an IC package structure with connections in accordance with still another embodiment of the present disclosure;

FIGS. 5-10 are schematic cross-sectional views illustrating a process flow of manufacturing the IC package structure with connections in accordance with one embodiment of the present disclosure; and

FIGS. 11-12 are schematic cross-sectional views illustrating a process flow of manufacturing the IC package structure with connections in accordance with another embodiment of the present disclosure.

All the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference will now be made in detail to exemplary embodiments of the disclosure, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something). Further, spatially relative terms, such as “beneath,” “below,” “lower,” “above,” “upper,” and the like, may be used herein for ease of description to describe one element or feature relationship to another element(s) or feature(s) as illustrated in the figures.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. Additionally, the term “based on” may be understood as not necessarily intended to convey an exclusive set of factors, but may allow for the presence of other factors not necessarily expressly described, again depending at least in part on the context.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

The following embodiments and figures will be exemplified with only a single IC package structure, that is, one unit of IC chip after package singulation. However, before package singulation, there may be multiple dies bonded to a single leadframe and one molding compound encapsulating all of the dies and connections, and for the sake of simplicity of illustration, the PCB board to which the leadframe be connected will not be shown in the drawings.

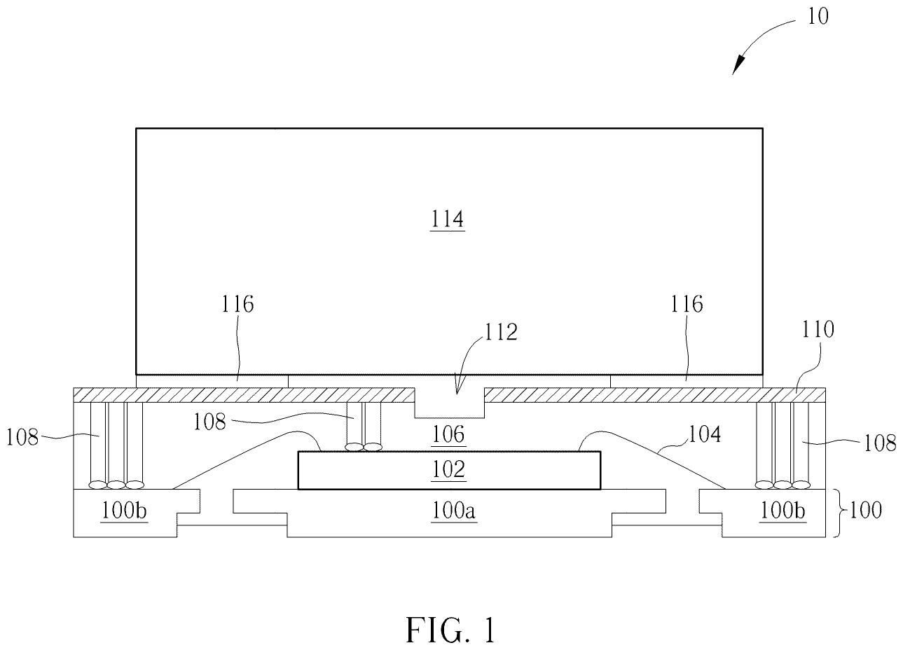

First, referring to FIG. 1, which is a schematic cross-sectional view of an IC package structure with connections in accordance with one embodiment of the present application. As shown in FIG. 1, the IC package structure 10 includes a leadframe 100 as a basis for components of the IC package structure 10 to be formed or disposed thereon. The leadframe 100 is a metal structure inside the package structure that carries signals from a die 102 to the external circuit, such as a PCB board, and is often used in DIP (Dual In-line Package), QFP (Quad Flat Package) and other packages where connections (ex. pins) to the chip or PCB board are made on its edges. The leadframe 100 consists of a die pad 100a on which the die 102 is placed, with coupling from the die pad 100a to several inner leads 100b positioned around the die pad 100a. The leadframe 100 may be manufactured by removing material from a flat plate of copper, copper-alloy, or iron-nickel alloy like alloy 42.

Referring still to FIG. 1. The die 102 is an integrated circuit (IC), which is a small block of semiconducting material on which a given functional circuit is fabricated. Typically, the dies 102 are produced in large batches on a single wafer of electronic-grade silicon (EGS) or other semiconductor (such as GaAs) through processes such as photolithography. The processed wafer is then cut (diced) into many pieces, each containing one copy of the die 102. The die 102 may be adhesively fixed on the die pad 100a through adhesive, such as epoxy resin. In the embodiment, the die 102 is electrically connected to the inner leads 100b of the leadframe 100 through individual bonding wires 104, such as copper wire, gold wire or silver wire.

Referring still to FIG. 1. One feature of the present application is that there is a plurality of connections 108 electrically connected on the inner leads 100b of the leadframe 100. The connections 108 here can be seen as an example of extending vertically from the inner leads 100b to provide connections from the leadframe 100 to the component 114 above. In some embodiments, there may be other connections 108 electrically connected on the die 102 for additional signal connection. In the present application, the connection 108 may be a conductive wire or a conductive post made of, but not limited to, copper. In the embodiment, a molding compound 106, such as epoxy resin, completely encapsulates the aforementioned die 102, bonding wires 104, connections 108 and the leadframe 100, except the pins of leadframe 100 for connecting external circuits, ex. a PCB board.

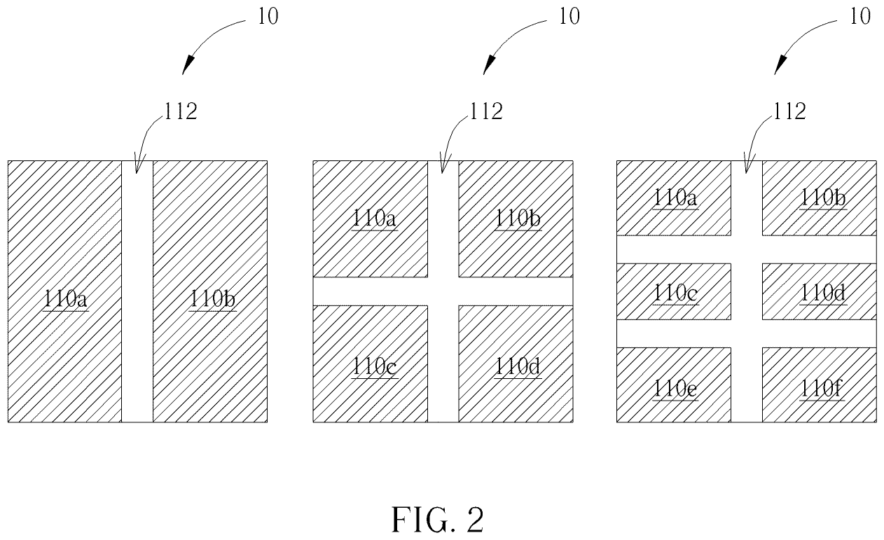

Referring still to FIG. 1. In the present disclosure, a metal layer 110 is formed on the top surface of the molding compound 106, and an end of each connection 108 is exposed from the molding compound 106 and electrically connected with the metal layer 110. The metal layer 110 may be made of conductive metal like copper. Furthermore, as shown in FIG. 1, a groove 112 is formed extending through the metal layer 110 to the molding compound 106. In the present disclosure, the groove 112 divides the metal layer 110 into multiple terminal areas (ex. 110a, 110b shown in FIG. 2), wherein each terminal area may function as one terminal of the IC package structure to electrically connect one terminal of a component 114 to be mounted thereon.

In the present disclosure, there may be a plurality of grooves 112 formed on the metal layer 110. As shown in FIG. 2, which is a schematic top view of metal layers 110 in several IC package structures 10, a groove 112 are formed on the metal layer 110 to divide the metal layer 110 into multiple electrically individual terminal areas 110a-110f. The number of terminal areas is preferably even number, for each two of the terminal areas 110a-110f being designed to electrically and correspondingly connect with two terminals of one electronic component mounted on the metal layer. Put it more clearly, referring again to FIG. 1, in the present disclosure, the electronic component 114 is mounted on the top surface of the metal layer 110 through the leads 116, such as J-leads, gull-wings, bonding pads or even just solder paste. The leads 116 are coupled in groups to one or more terminal areas 110a-110f (FIG. 2) of the metal layer 110, which is divided by the groove 112. For example, two adjacent leads are coupled to one terminal area. The electronic component 114 may include, but not limited to, inductor, capacitor, resistor, diodes, transistor, connector, LED, sensor or micro switch.

Through the aforementioned architecture, additional electronic component(s) 114 may be designed and disposed right on an IC package structure in the present disclosure, thus the component density of a PCB board under unit area can be significantly increased without additional layout area. The electronic component 114 mounted on the IC package structure 10 may be electrically connected to the leadframe 100 inside the package through the connections 108, and be further connected to the die 102 bonded to the leadframe 100 and the PCB board (no shown) below the leadframe 100 for signal transmission. The die 102 may also be electrically connected to the metal layer 110 and the electronic component 114 above through the connections 108 disposed thereon, for purpose of facilitating the circuit design and modification.

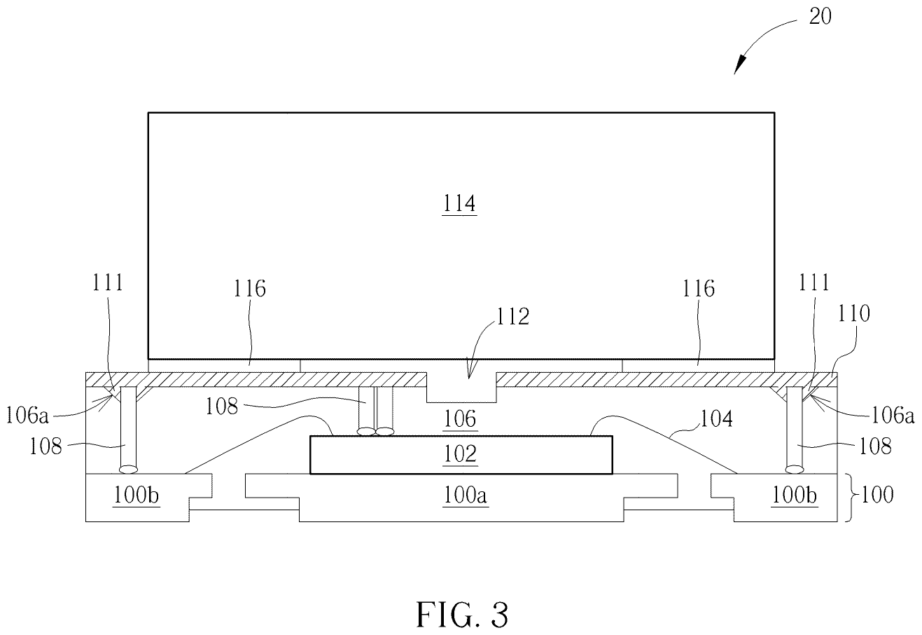

Referring to FIG. 3, which is a schematic cross-sectional view of an IC package structure 20 with connections in accordance with another embodiment of the present disclosure. This embodiment is characterized by a modified design of connections 108. The connection 108 bonded to the inner leads 100b of the leadframe 100 extends to the metal layer 110 above for signal connection. In addition, an extension part 111 of the metal layer 110 is formed surrounding the end of each connection 108. The extension part 111 fills up the dimple 106a formed on the top surface of the molding compound 106, and the end of connection 108 extends upwardly from the molding compound 106 to the dimple 106a without exceeding the top surface of the molding compound 106, so that the extension part 111 of the metal layer 110 formed in the dimple 106a will surround the end of connection 108, to improve the connection and structural strength between the connection 108 and the metal layer 110, which is an advantage of this design in the present disclosure.

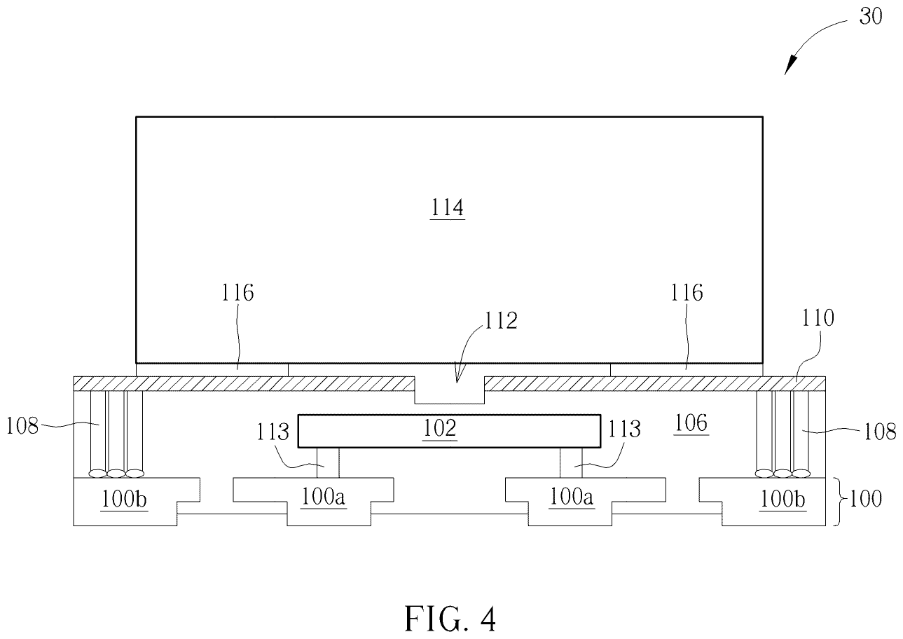

Referring to FIG. 4, which is a schematic cross-sectional view of an IC package structure 30 with connections in accordance with another embodiment of the present disclosure. This embodiment is specifically for the application of flip-chip package in comparison to the wire bonding package in previous embodiments. The die 102 in this embodiment is specifically a flip-chip die, which may be bonded to the die pad 100a of the leadframe 100 below, for example in a grid array, through the leads 113 on the bottom surface of the die 102, such as solder balls, copper pillars, microbumps or even conductive adhesives. The space between the die 102 and the die pad 100a may be filled with underfill (no shown) to provide a stronger mechanical connection and heat bridge. The benefit of this design includes improved electrical performance, higher I/O density, better thermal management and reduced package size, in comparison to traditional wire bonding technology.

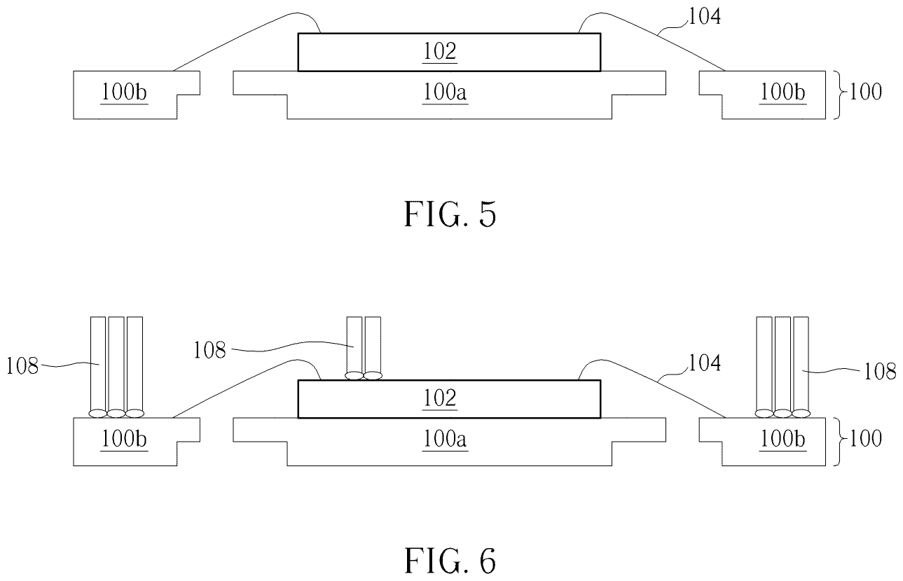

After describing the aforementioned IC package structures 10, 20, 30 of the present disclosure, the following embodiments will illustrate a process of manufacturing the IC package structure of the present disclosure with reference to FIGS. 5-10 sequentially. These drawings will take the IC package structure 10 (i.e. wire bonding package) as an example to explain the evolution and formation of the components in IC package structure 10 during the manufacturing process in the form of cross-sections. Before package singulation, there may be multiple dies bonded to a single leadframe and one molding compound encapsulating all of the dies and connections. The embodiments and figures are exemplified with only a single IC package structure, that is, one unit of IC chip after package singulation, for the simplicity of illustration.

Referring to FIG. 5, at the beginning of the process, a leadframe 100 is provided as a basis for components of the IC package structure 10 to be formed or disposed thereon. The leadframe 100 consists of a die pad 100a on which the die 102 is placed, with coupling from the die pad 100a to several inner leads 100b positioned around the die pad 100a. The leadframe 100 may be manufactured by removing material from a flat plate of copper, copper-alloy, or iron-nickel alloy like alloy 42, through etching or stamping process. In the case of wire bonding design, the die 102 is first adhesively fixed on the die pad 100a through adhesive, such as epoxy resin. Thereafter, a wire bonding process is performed to electrically connect the die 102 to the inner leads 100b of the leadframe 100 through individual bonding wires 104, such as copper wire, gold wire or silver wire. The process may include a ball formation step to form a ball at one end of the bonding wire 104 through a small amount of heat and pressure. The wire with its formed ball is placed and bonded to a contact pad on the die 102 (no shown) using heat, pressure and ultrasonic energy, which creates a strong electrical connection. The wire is then looped over and bonded to the corresponding inner leads 100b of the leadframe 100 with the same method to establish the electrical connection between the die 102 and the inner leads 100b.

Referring to FIG. 6. After the die 102 is bonded with the leadframe 100, a plurality of connections 108 is formed on the inner leads 100b of the leadframe 100. In the present disclosure, the connection 108 is formed electrically bonding with the leadframe 100 and extending vertically from the leadframe 100 to a predetermined height. The connection 108 may also be formed and electrically connected on the die 102 to provide additional signal connection. The connection 108 may be conductive wires or conductive posts, such as copper wire or copper post, which may be formed through any suitable process that can create stable, rigid, vertical conductive path to the predetermined height.

In the present disclosure, the connections 108 are formed before the package molding process. This is quite distinguishing from the approach of conventional skill, which often uses vias (vertical interconnect accesses) to connect the inner leads of the leadframe. The vias is usually formed by first forming via holes in the molding compound and then filling up the via holes with conductive material, which may be referred as through molding via (TMV). The disadvantage of the conventional skill is high cycle time and cost, and may easily suffer adhesion issue after electronic components are mounted.

Referring to FIG. 7. After the connections 108 are formed, the protective molding compound 106 is formed on the leadframe 100. In the present disclosure, the molding compound 106 is formed completely encapsulating the die 102, the bonding wires 104 and the connections 108. The material of molding compound 106 may be epoxy resin. The step of molding process may include injecting the molding material into a mold with the die 102 and leadframe 100 mounted therein under heat and pressure. This step ensures the die 102 is fully covered, protecting the die 102 from environmental factors such as moisture, dust and mechanical damage. The molding material is then cured and solidified into the molding compound 106 by heat, which encapsulates the aforementioned components. Some parts of the leadframe 100, such as the pins for connecting external circuits of a PCB board, will not be encapsulated by the molding compound 106.

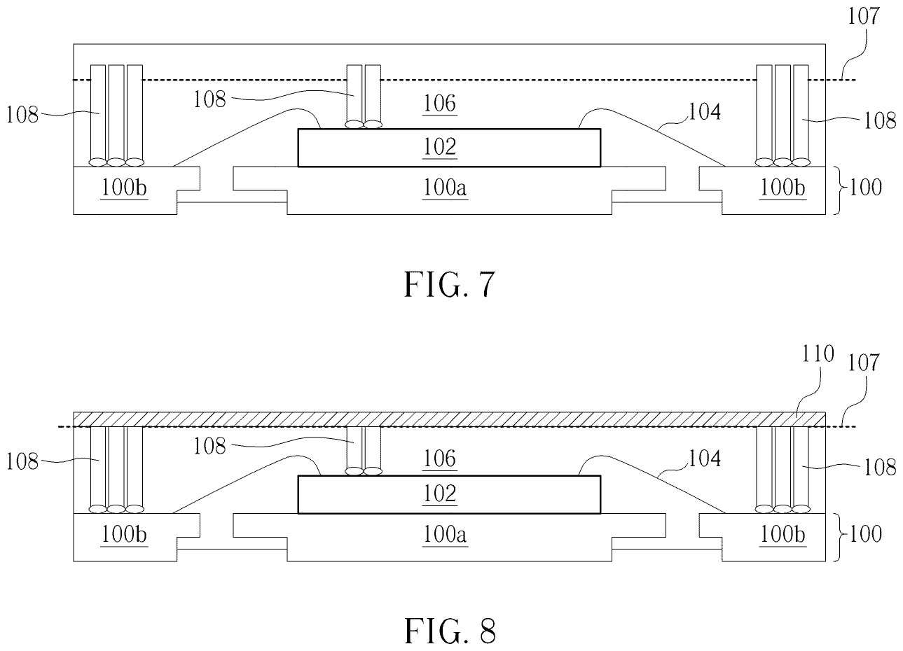

Referring to FIG. 8. After the package encapsulation, a grinding process is first performed to reduce the height of the top surface of the molding compound 106 to a predetermined level, ex. the dashed line 107 shown in FIG. 7, so that the top end of each of the connections 108 is exposed from the molding compound 106 for subsequent electrical connection. Thereafter, the metal layer 110 is formed on a top surface of the molding compound 106, wherein the top end of each of the connections 108 is electrically connected with the metal layer 110, including both the connections 108 on the inner leads 100b and the connections 108 on the die 102. In the present disclosure, the metal layer 110 may be formed through process like sputtering, plating, coating or taping, with material like copper.

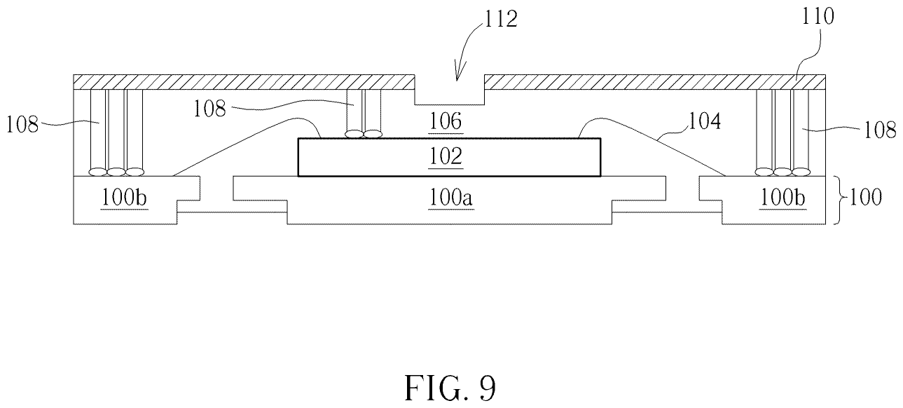

Referring to FIG. 9. After the metal layer 110 are formed, form a groove 112 on the metal layer 110. In the present disclosure, the groove 112 is formed extending downwardly through the metal layer 110 to the molding compound 106 and dividing the metal layer 110 into multiple terminal areas, such as the terminal areas 110a-110f in FIG. 2. The groove 112 may be formed by removing parts of the metal layer 110 and the molding compound 106 through laser cutting or blade cutting.

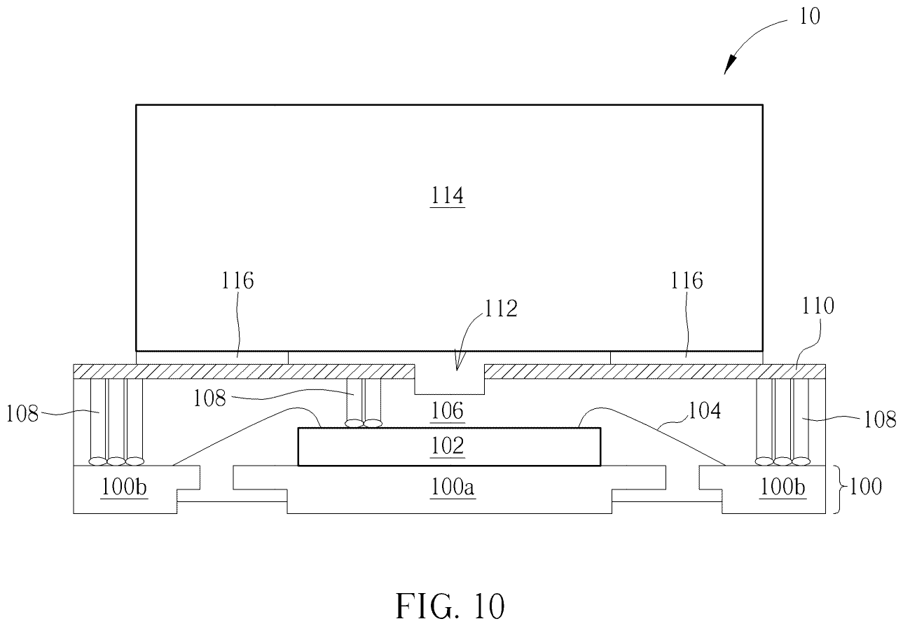

Referring to FIG. 10. After the groove 112 is formed, mount an electronic component 114 on the metal layer 110. The electronic component 114 may be mounted on the top surface of the metal layer 110 through surface-mount technology (SMT), with each leads 116 of the electronic component 114 connecting to one terminal area 110a-110f (FIG. 2) of the metal layer 110 divided by the groove 112. The electronic component 114 may include, but not limited to, inductor, capacitor, resistor, diodes, transistor, connector, LED, sensor or micro switch.

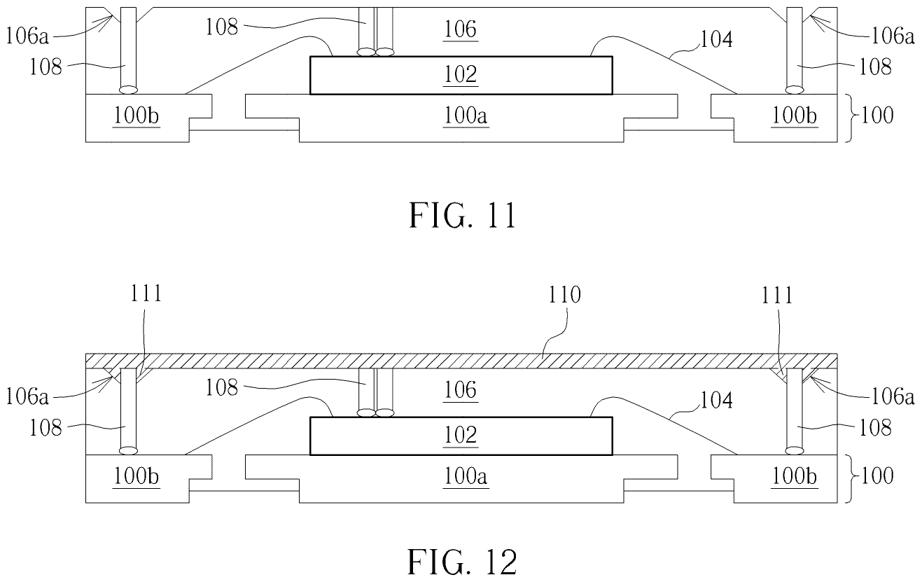

Referring now to FIGS. 11-12, which are schematic cross-sectional views illustrating a process flow of manufacturing the IC package structure with connections in accordance with another embodiment of the present disclosure.

In this embodiment, as shown in FIG. 11, a dimple 106a is formed on the top surface of the molding compound 106 around the top end of each connection 108 except the connection 108 on the die 102. The dimple 106a may be formed by removing parts of the molding compound 106 through laser drilling after the molding compound 106 is grinded to expose the top ends of the connections 108. After the dimples 106a are formed, the top end of connection 108 will extend upwardly from the molding compound 106 to the dimple 106a without exceeding the top surface of the molding compound 106. This may facilitate the connection between the connections 108 and subsequent metal layer 110.

Referring to FIG. 12. After the dimples 106a are formed, similar to the process of FIG. 8, a metal layer 110 is formed on the top surface of the molding compound 106 to electrically connect the connections 108 in the molding compound 106. In the embodiment, the formed metal layer 110 will be provided with an extension part 111 formed in each dimple 106a. These extension parts 111 surround the top ends of the connections 108, improving the connection and structural strength between the connections 108 and the metal layers 110.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An IC package structure with connections, comprising:
a leadframe;
a die bonded to the leadframe;
a plurality of connections bonded to the leadframe;
a molding compound positioned on the leadframe, wherein the molding compound encapsulates the die and the connections;
a metal layer positioned on the molding compound, wherein an end of each of the connections is electrically connected with the metal layer; and
an electronic component mounted on the metal layer.

2. The IC package structure with connections of claim 1, wherein the connections are conductive wires.

3. The IC package structure with connections of claim 1, wherein the connections are conductive posts.

4. The IC package structure with connections of claim 1, further comprising a dimple formed on the molding compound around each of the connections, wherein the metal layer comprises an extension part formed in each of the dimples and surrounding the end of each of the connections.

5. The IC package structure with connections of claim 1, further comprising a groove extending through the metal layer to the molding compound and dividing the metal layer into multiple terminal areas.

6. The IC package structure with connections of claim 5, wherein the electronic component is electrically bonded with two of the terminal areas.

7. The IC package structure with connections of claim 1, wherein the electronic component is inductor, capacitor, resistor, diodes, transistor, connector, LED, sensor or micro switch.

8. The IC package structure with connections of claim 1, further comprising one of other connections coupled between the die and the metal layer.

9. The IC package structure with connections of claim 1, wherein the die is bonded to the leadframe through bonding wires.

10. The IC package structure with connections of claim 1, wherein the die is flip-chip die and is bonded to the leadframe through solder balls, copper pillars, microbumps or conductive adhesives.

11. The IC package structure with connections of claim 1, wherein the IC package structure is quad flat no lead (QFN) package structure.

12. A method of manufacturing IC package structure with connections, comprising:
providing a leadframe with multiple die pads;
adhering a die on each of the die pads of the leadframe;
electrically bonding the die to the leadframe;
forming a plurality of connections electrically bonded to the leadframe;
after the connections are formed, forming a molding compound on the leadframe, wherein the molding compound encapsulates the die and the connections;
forming a metal layer on the molding compound, wherein an end of each of the connections is electrically connected with the metal layer; and
mounting an electronic component on the metal layer.

13. The method of manufacturing IC package structure with connections of claim 12, wherein the die are bonded to the leadframe through wire bonding.

14. The method of manufacturing IC package structure with connections of claim 12, wherein the die are bonded to the leadframe by flip-chip process through solder balls, copper pillars, microbumps or conductive adhesives.

15. The method of manufacturing IC package structure with connections of claim 12, further comprising forming a dimple on the molding compound around each of the connections, wherein the metal layer comprises an extension part formed in each of the dimples and surrounding the end of each of the connections.

16. The method of manufacturing IC package structure with connections of claim 15, wherein the dimple is formed through laser drilling.

17. The method of manufacturing IC package structure with connections of claim 12, further comprising forming a groove extending through the metal layer to the molding compound and dividing the metal layer into multiple terminal areas.

18. The method of manufacturing IC package structure with connections of claim 17, wherein the groove is formed through laser cutting or blade cutting.

19. The method of manufacturing IC package structure with connections of claim 12, wherein the electronic component is mounted on the metal layer through surface-mount technology.

20. The method of manufacturing IC package structure with connections of claim 19, wherein the metal layer are formed on the top surface of the molding compound through sputtering, plating, coating or taping.
